(19) United States
(12) Patent Application Publication
(10) Pub. No.: US 2004/0232558 A1
(43) Pub. Date: Nov. 25, 2004

(54) Semiconductor device and method of manufacturing the same

(75) Inventor: Mami Toda, Kawasaki-shi (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION

(21) Appl. No.: 10/759,273

(22) Filed: Jan. 20, 2004

(30) Foreign Application Priority Data
Jan. 20, 2003 (JP) 10567/2003

(51) Int. Cl. H01L 23/48; H01L 21/4763

(52) U.S. Cl. 257/774; 438/629; 438/637; 257/776

(57) ABSTRACT

A semiconductor device has an insulating film. An interconnect groove or a via hole is formed in the insulating film. An interconnect pattern or a via hole is buried in the interconnect groove or the via hole. A substantially flat hard mask is formed on the interconnect pattern. The hard mask is provided with an opening portion having a width narrower than a space between adjacent interconnect patterns and is made of a material that is etched selectively with the insulating film.

This application claims priority to prior application JP 2003-10567, the disclosure of which is incorporated herein by reference.

### BACKGROUND OF THE INVENTION

This invention relates to a semiconductor device and a method of manufacturing the same and, in particular, to a semiconductor device provided with an interconnect and a via formed by the use of a damascene process.

Recently, as a semiconductor device is highly integrated and is reduced in chip size, an interconnect structure is progressively miniaturized and multilayered. As a method of forming a multilayer or multilevel interconnect structure, a process called a damascene method or process is generally used. In such a damascene process, after a via hole or an interconnect groove is formed in an insulating film, a conductive material is deposited on an entire surface of a substrate and is polished by chemical mechanical polishing (CMP). As a consequence, the conductive material is buried in the via hole or the interconnect groove. This process is typically used as a method of forming the multilayer interconnect structure using a copper-based conductive material which is difficult to process by etching.

Referring to FIGS. 1A to 1D and 2, description will be made of the above-mentioned conventional damascene process (hereinafter, will be referred to as a first conventional example).

At first, as illustrated in FIG. 1A, on a semiconductor substrate 1 provided with a MOS transistor and the like, a first etching stopper film 2 made of SiNx or the like and a first insulating film 3 made of SiO₂ or the like are successively deposited. Then, using a resist pattern formed by the known photolithography as a mask, a plurality offirst interconnect grooves penetrating through the first insulating film 3 and the first etching stopper film 2 are formed by the use of the known dry-etching. Subsequently, a barrier metal film made of Ti, Ta, or the like for preventing an interconnect material from being diffused is deposited thereon. Further, Cu is depositedthereon by electroplating or the like. Then, Cuand the barrier metal film deposited and formed on the first insulating film 3 are removed by CMP to thereby form a first layer interconnect pattern 14 in the first interconnect groove.

Next, as shown in FIG. 1B, a second etching stopper film 4 made of SiNx or the like and a first interlayer insulating film 5 made of SiO₂ or the like are successively deposited. Similarly, using the known photolithography and dry-etching, a plurality of first via holes penetrating through the first interlayer insulating film 5 and the second etching stopper film 4 are formed. After a barrier metal film and Cu are deposited, a plurality of second-to-first layer interconnection vias 15 are formed in the first via holes by CMP. Thereafter, by repeating the similar process, a second layer interconnect pattern 16 illustrated in FIG. 1C, a plurality of third-to-second layer inter connection vias 17 illustrated in FIG. 1D, and a third layer interconnect pattern 18 illustrated in FIG. 2 are successively formed. It is noted here that the second-to-first layer interconnection vias 15 serve to connect the second and the first layer interconnect patterns 16 and 14 and will simply be called the “second-to-first vias” hereinafter. Likewise, the third-to-second layer interconnection vias 17 serve to connect the third and the second layer interconnect patterns 18 and 16 and will simply be called the “third-to-second vias” hereinafter.

By the aforementioned method, the semiconductor device having the multilayer interconnect structure can be formed. Such a method is, however, disadvantageous in the following respect. In the second insulating film 7, second layer interconnect patterns 16 must be formed also at positions connecting the third-to-second vias 17 and the second-to-first vias 15 (in a path labeled E in FIG. 2) in order tosupply an electric potential from the third layer interconnect pattern 18 to the first layer interconnect pattern 14. In this event, the pitch between the second layer interconnect patterns 16 in paths labeled D and F can not be reduced and, therefore, an interconnect layout is problematically restricted.

In order to reduce the pitch between the interconnect pattern (which may be referred to as the interconnect pitch), a technique for forming a via directly connecting the interconnect patterns apart from each other (for example, the first layer interconnect pattern 14 and the third layer interconnect pattern 18) in a self-aligned manner is used. The technique is called self-aligned contact (SAC). A method of manufacturing a semiconductor device using the above-mentioned SAC is disclosed, for example, in Japanese Unexamined Patent Publication (JP-A) No. 2002-151587 (corresponding to US 2002/0058371 A1). Referring to FIGS. 3 and 4, description will be made of the method (will be referred to as a second conventional example hereinafter) disclosed in the aforementioned publication.

At first, in the manner similar to the first conventional example, on the semiconductor substrate 1, the first etching stopper film 2 and the first insulating film 3 are successively deposited and the first interconnect grooves are formed therethrough. Then, the first layer interconnect pattern 14 is buried in the first interconnect groove by CMP. Then, the second etching stopper film 4 and the first interlayer insulating film 5 are successively deposited and the first via holes are formed therethrough. Then, the second-to-first vias 15 are formed in the first via holes by CMP.

Subsequently, as shown in FIG. 3A, on the first interlayer insulating film 5, a metal film to serve as the second layer interconnect pattern 16 land a SiNx film having a thickness of about 70 nm are deposited. Then, using a resist pattern formed thereon as a mask, the metal film and the SiNx film are simultaneously etched to thereby form the second layer interconnect pattern 16 and a nitride film mask 24 with a predetermined line width and a line space.

Next, as illustrated in FIG. 3B, a blanket nitride film is deposited throughout the entire surface by thermal CVD and etched back by anisotropic dry-etching to form a sidewall nitride film 25 having a film thickness of about 50 nm on the sidewall of the second layer interconnect pattern 16 and the nitride film mask24.

Subsequently, as shown in FIG. 3C, in order to cover the nitride film mask 24 and the sidewall nitride film 25, the second interlayer insulating film 11 is deposited. After the second interlayer insulating film 11 is flattened by CMP, a resist pattern for forming the second via hole 23 is formed by the known photolithography. Using a combination of the resist pattern, the nitride film mask 24, and the sidewall nitride film 25, the second interlayer insulating film 11, the first interlayer insulating film 5, and the second etching stopper film 4 are successively etched to form the second via hole 23 by the known dry-etching.

Thereafter, as illustrated in FIG. 4A, the barrier metal film and Cu are deposited throughout the entire surface and a third-to-first via 19 is formed in the second via hole 23 by CMP. Subsequently, as shown in FIG. 4B, on the third-to-first layer via 19, a third layer interconnect pattern 18 is formed in the similar manner.

In the above-mentioned method, the third-to-first layer via 19 is formed in the self-aligned manner by the help of a combination of the nitride film mask 24 and the sidewall nitride film 25 as a mask. Therefore, the interconnect pitch of the second layer interconnect pattern 16 can be reduced as compared with the first conventional example, so as to achieve the miniaturization of the semiconductor device.

In the second conventional example, the dry-etching for forming the second via hole 23 is performed by the use of reactive ion etching (RIE). In RIE, a mixed gas of C₄F₈, oxygen, and argon is used as a reactive gas so that the ratio between the etching rate of the silicon oxide films (the second interlayer insulating film 11 and the first interlayer insulating film 5) and the etching rate of the silicon nitride films (the nitride film mask 24 and the sidewall nitride film 25) is increased, making it possible to selectively etch the silicon oxide films. However, it is difficult to control the thickness and the shape of the sidewall nitride film 25. In particular, a part of the sidewall nitride film 25 which is located at a corner of the nitride film mask 24 tends to be thin. Therefore, depending upon the thickness of the second and the first interlayer insulating films 11 and 5, the nitride film mask 24 and the sidewall nitride film 25 may be excessively etched beyond expectation. This may cause short-circuiting between the second layer interconnect pattern 16 and the third-to-first via 19.

In order to avoid the short-circuiting mentioned above, it is required that the nitride film mask 24 and the sidewall nitride film 25 are increased in thickness. However, such an increase in thickness results in an increase in an aspect ratio (h2/w2 in FIG. 3B) of a region surrounded by the sidewall nitride film 25. In this event, upon forming the second interlayer insulating film 11 in the step of FIG. 3C, it is difficult to sufficiently and completely bury the above-mentioned region. This results in easy occurrence of a void 26 caused by the buried defect as illustrated in FIG. 4B. If the void 26 is formed between adjacent second layer interconnect patterns 16, the shape of the via is deformed so that the third-to-first layer via 19 adjacent in the direction of the second layer interconnect pattern 16 is short-circuited.

### SUMMARY OF THE INVENTION

It is therefore an object of this invention to provide a semiconductor device which has a damascene structure and which is capable of reducing an interconnect pitch without the risk of short-circuiting of adjacent interconnect patterns or vias.

It is another object of this invention to provide a method manufacturing the above-mentioned semiconductor device.

Other objects of this invention will become clear as the description proceeds.

According to a first aspect of this invention, there is provided a semiconductor device having an insulating film, comprising:

an interconnect groove or a via hole which is formed in the insulating film;

an interconnect pattern or a via hole which is buried in the interconnect groove or the via hole; and

a substantially flat hard mask which is formed on the interconnect pattern and which is provided with an opening portion having a width narrower than a space between adjacent interconnect patterns and which is made of a material that is etched selectively with the insulating film.

Preferably, the hard mask comprises a slit-like opening portion which is formed in an extending direction of the interconnect pattern located below the hard mask.

According to a second aspect of this invention, there is provided a semiconductor device having an insulating film, comprising:

an interconnect groove or a via hole which is formed in the insulating film;

an interconnect pattern or a via hole which is buried in the interconnect groove or the via hole, a third layer interconnect pattern which is formed on the second layer interconnect pattern, the third layer interconnect pattern being connected to the first layer interconnect pattern through a third-first layer interconnection via penetrating a space between adjacent second layer interconnect patterns; and

a first layer interconnect pattern;

a second layer interconnect pattern which is formed on the first layer interconnect pattern;

a substantially flat hard mask which is formed on the second interconnect pattern and which is provided with an opening portion specifying a shape of the third-first layer interconnection via and which is made of a material that is etched selectively with the insulating film.

Preferably, the hard mask comprises a slit-like opening portion which is formed in an extending direction of the interconnect pattern located below the hard mask.

According to a third aspect of this invention, there is provided a method of manufacturing a semiconductor device, comprising the steps of:

forming an interconnect groove or a via hole in a insulating film formed on a substrate;

forming an interconnect pattern or a via by burying an interconnect material containing at least one of copper and tungsten in the interconnect groove or the via hole; and

forming a substantially flat hard mask which is made of a material that can be etched selectively with the insulating film except for a region having a width narrower than a space between adjacent interconnect patterns on the interconnect pattern after forming the interconnect pattern.

Preferably, the opening portion of the hard mask is formed to a slit form in an extending direction of the interconnect pattern located below the hard mask.

According to a fourth aspect of this invention, there is provided a method of manufacturing a semiconductor device, comprising the steps of:

forming an interconnect groove or a via hole in a insulating film formed on a substrate;

forming an interconnect pattern or a via by burying an interconnect material containing at least one of copper and tungsten in the interconnect groove or the via hole;

forming a first cover insulating film on the interconnect pattern after forming the interconnect pattern;

forming a first resist pattern including an opening portion having a width narrower than a space between adjacent interconnect patterns on the first cover insulating film;

etching the first cover insulating film by using the first resist pattern as a first mask;

depositing a second cover insulating film which can be etched selectively with the first cover insulating film so as to cover the first cover insulating film after removing the first resist pattern;

forming a substantially flat hard mask which is buried with the first cover insulating film between the second cover insulating film by polishing the second cover insulating film by etchback or CMP;

forming an interlayer insulating film on the hard mask;

forming a second resist pattern having an opening portion which is equivalent to or wider than that of the first cover insulating film on the interlayer insulating film; and

forming the via hole by etching the interlayer insulating film and the first cover insulating film using the second resist pattern as a second mask and by etching the insulating film using the second cover insulating film as a third mask.

Preferably, the second cover insulating film is formed by a material that can be etched selectively with the insulating film and the interlayer insulating film.

Preferably, the opening portion of the hard mask is formed to a slit form in an extending direction of the interconnect pattern located below the hard mask.

According to a fifth aspect of this invention, there is provided a method of manufacturing a semiconductor device, comprising the steps of:

forming an interconnect groove or a via hole in a insulating film formed on a substrate;

forming an interconnect pattern or a via by burying an interconnect material containing at least one of copper and tungsten in the interconnect groove or the via hole;

forming a cover insulating film on the interconnect pattern after forming the interconnect pattern;

forming a first resist pattern including an opening portion having a width narrower than a space between adjacent interconnect patterns on the cover insulating film;

forming a substantially flat hard mask by etching the cover insulating film using the first resist pattern as a first mask;

forming an interlayer insulating film on the hard mask after removing the first resist pattern;

forming a second resist pattern having an opening portion which is equivalent to or wider than that of the first cover insulating film on the interlayer insulating film; and

forming the via hole by etching the interlayer insulating film using the second resist pattern as a second mask and by etching the insulating film using the second cover insulating film as a third mask.

Preferably, the cover insulating film is formed by a material that can be etched selectively with the insulating film and the interlayer insulating film.

Preferably, the opening portion of the hard mask is formed to a slit form in an extending direction of the interconnect pattern located below the hard mask.

Thus, according to this invention, after forming the interconnect pattern, the hard mask having small irregularity (unevenness) is formed on the interconnect pattern by the use of the cover insulating film having high selectivity with respect to the interlayer insulating film located thereunder. With this structure, buriability of the interlayer insulating film formed on the interconnect pattern is improved so that the void formation is suppressed and the short-circuiting of the interconnect pattern and the via is avoided. In particular, the hard mask has a structure in which the region to become the opening portion is buried or filled with the insulating film similar to the interlayer insulating film. With this structure, it is possible to form the hard mask having a substantially flat shape and to reliably prevent the buried defect of the interlayer insulating film.

Further, when the etching is carried out by the use of the resist pattern formed on the interlayer insulating film, the via hole connecting the upper layer interconnect pattern and the lower layer interconnect pattern is formed in a self-aligned manner. Therefore, the interconnect pitch of the interconnect pattern penetrated by the via can be reduced so that the restriction imposed upon the interconnect layout can be relieved.

### BRIEF DESCRIPTION OF THE DRAWINGS

FIGS. 1A through 1D are sectional views for describing a method of manufacturing a semiconductor device using a singledamascene process according to a first conventional example;

FIG. 2 is a sectional view similar to FIGS. 1A through 1D;

FIGS. 3A through 3C are sectional views for describing a method of manufacturing a semiconductor device using a hard mask having a sidewall structure according to a second conventional example;

FIGS. 4A and 4B are sectional views similar to FIGS. 3A through 3C;

FIGS. 5A through 5D are sectional views for describing a method of manufacturing a semiconductor device using a dual damascene process according to a first embodiment of this invention;

FIGS. 6A through 6C are sectional views similar to FIGS. 5A through 5D;

FIGS. 7A through 7C are sectional views similar to FIGS. 5A through 5D;

FIG. 8 is a sectional view similar to FIGS. 5A through 5D;

FIG. 9 is a sectional view showing a semiconductor memory device having a COB (Capacitor Over Bitline) structure formed by the method according to the first embodiment of this invention;

FIGS. 10A through 10C are sectional views for describing a method of manufacturing a semiconductor device using a dual damascene process according to a second embodiment of this invention; and

FIGS. 11A through 11C are sectional views similar to FIGS. 1A through 10C.

### DESCRIPTION Of PREFERRED EMBODIMENTS

Prior to description of preferred embodiments, the concept of this invention will be described in comparison with the conventional examples.

In the structure described in conjunction with the first conventional example, the interconnect patterns apart from each other (for example, the first layer and the third layer interconnect patterns) are connected by the use of the interconnect pattern and the vias formed in the intermediate layers. In this case, the interconnect patterns are concentrated in the intermediate layer (the second layer interconnect pattern). As a result, the interconnect pitch can not be reduced, preventing the miniaturization of the semiconductor device. On the other hand, in the method described in conjunction with the second conventional example, the third-to-first via is formed in a self-aligned manner by the use of the nitride film mask and the sidewall nitride film formed on the second layer interconnect pattern. In this case, if the nitride film mask and the sidewall nitride film are sufficiently thick so as to prevent the short-circuiting, the region surrounded by the sidewall nitride film has a high aspect ratio. As a consequence, it is difficult to sufficiently and completely bury the interlayer insulating film so that the void resulting from the buried defect is problematically formed.

In order to reduce the interconnect pitch as small as possible, it is necessary to accurately control the shape of the via. In the method of forming the via hole by the use of the nitride film mask and the sidewall nitride film, however, it is difficult to control the thickness and the shape of the sidewall nitride film. Further, as the etching proceeds, a broadened base of the sidewall nitride film is etched off so that the shape of the opening portion is varied. As a consequence, the diameter of the via is undesirably fluctuated. This prevents the semiconductor device from being miniaturized because a wide margin must be designed.

In order to reduce the interconnect pitch, it is effective to use a hard mask formed by a material having a high etching selectivity with respect to the interlayer insulating film. In the hard mask of the sidewall structure disclosed in the second conventional example, however, the hard mask itself has a large irregularity and, therefore, it is difficult to completely and sufficiently bury the interlayer insulating film. Consequently, the formation of the void can not be avoided. In order to eliminate the buried defect of the interlayer insulating film caused by such irregular hard mask, the present inventor proposes a method of forming a substantially flat hard mask on the interconnect pattern after forming the interconnect pattern. As described above in conjunction with the second conventional example, the method of forming the via by the use of the hard mask is known. However, the technique of forming, on the interconnect pattern, a hard mask without the irregularity or having small irregularity is newly proposed by the present inventor. By using this technique, the interconnect pitch can be reduced and, at the same time, the buried defect can be avoided.

Now, description will be made in detail of preferred embodiments of this invention with reference to the drawing.

### First Embodiment

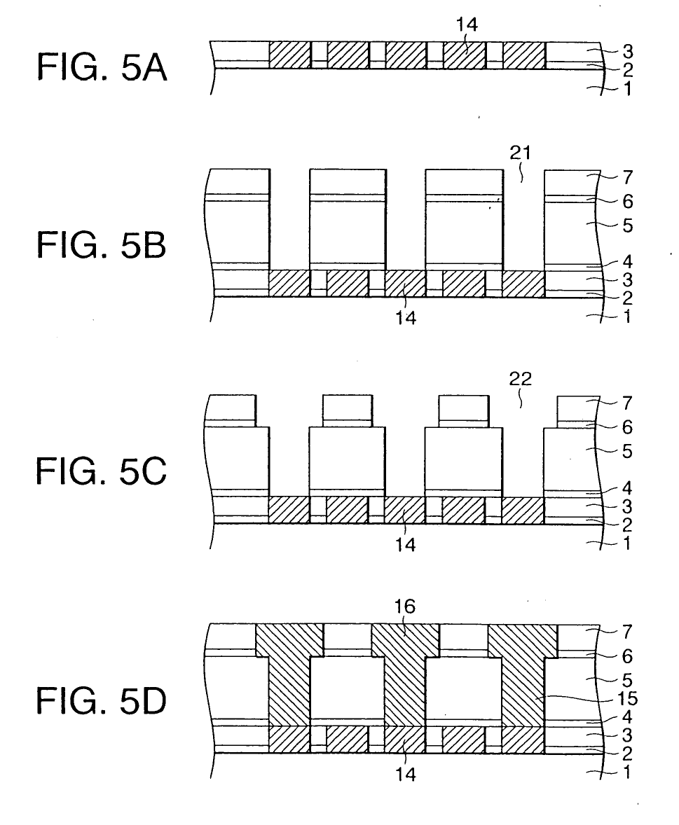

Referring to FIGS. 5A through 8, description will be made of a semiconductor device and a method of manufacturing the same according to a first embodiment of this invention.

It is noted here that the following description is directed to the case where a multilayer interconnect structure is formed by CMP using Cu or another interconnect material containing Cu as a material of an interconnect pattern and a via. However, this invention is not restricted to the following embodiments but is also applicable to the case where the multilayer interconnect structure or an interconnect pattern and a via as a part of the multilayer interconnect structure are formed by CMP or etchback using tungsten (W) as the material of the interconnect pattern and the via.

At first, on a semiconductor substrate 1 provided with a MOS transistor and the like, a first etching stopper film 2 made of SiNx, SiC, SiCN, or the like and a first insulating film 3 made of SiO₂ or the like are successively deposited by CVD, plasma CVD, or the like. Then, an antireflection film for suppressing reflection of exposure light and a chemically amplified resist are applied thereon. By exposure and development according to the KrF photolithography, a resist pattern for forming a plurality of first interconnect grooves is produced. Subsequently, using the known dry-etching, the first insulating film 3 and the first etching stopper film 2 are successively etched to form the first interconnect grooves penetrating therethrough. Thereafter, by oxygen plasma ashing and a wet process using an organic remover (organic peeling liquid), the resist pattern and the antireflection film are peeled off and a residue left after the dry-etching is removed.

Subsequently, a barrier metal film is deposited. The barrier metal film may be a single layer film such as Ti, TiN, Ta, TaN, WN, or the like or a lamination film comprising two or more layers as a combination of those films. Subsequently, a Cu seed metal for promoting the growth of Cu upon plating, which is used as an interconnect material, is formed. Then, by electroplating, Cu is deposited and buried in the first interconnect grooves. Thereafter, Cu and the barrier metal film on the first insulating film 3 are removed by CMP, and the first layer interconnect pattern 14 is buried in the first interconnect groove. In this manner, the structure illustrated in FIG. 5A is obtained. It is noted here that the materials of the first etching stopper film 2 and the first insulating film 3 are not specifically restricted but any combination of materials may be used as far as a desired etching selectivity is assured. Further, the thickness of these films may be selected as desired. In case where W is used as the interconnect material, TiN/Ti, TiN, or the like is deposited as the barrier metal film and, by CMP or etchback, W is buried in the first interconnect groove to form the first layer interconnect pattern 14 (this also applies to interconnect patterns and vias which will be formed later).

Next, as illustrated in FIG. 5B, on the first insulating film 3, a second etching stopper film 4 made of SiNx, SiC, SiCN, or the like, a first interlayer insulating film 5 formed of SiO₂, a low dielectric film, or the like, a third etching stopper film 6 made of SiNx, SiC, SiCN, or the like, and a second insulating film 7 made of SiO₂ or the like are successively deposited by CVD, plasma CVD, or the like. Then, a resist pattern (not shown) for forming a plurality of first via holes 21 is formed thereon. Thereafter, using the known dry-etching, the second insulating film 7, the third etching stopper film 6, and the first interlayer insulating film 5 are successively etched to thereby form the first via holes 21 penetrating therethrough. Then, the resist pattern is removed by the oxygen plasma ashing and the wet process using the organic remover. Herein, It is noted that the materials of the second etching stopper film 4, the first interlayer insulating film 5, the third etching stopper film 6, and the second insulating film 7 are not specifically restricted but any combination of materials may be used as far as a desired etching selectivity is assured. Further, the thickness of these films may be selected as desired.

Subsequently, as shown in FIG. 5C, on the second insulating film 7, a resist pattern (not shown) for forming a plurality of second interconnect grooves 22 is formed. Thereafter, using the known dry-etching, the second insulating film 7 is etched. Then, an exposed part of the third etching stopper film 6 and the second etching stopper film 4 at the bottom of each of the first via holes 21 are etched. Thereafter, the resist pattern is removed by the oxygen plasma ashing and the wet process using the organic remover.

Next, as illustrated in FIG. 5D, a barrier metal film is deposited. The barrier metal film may be a single layer film such as Ti, TiN, Ta, TaN, WN, or the like or a lamination film comprising two or more layers as a combination of those films. Subsequently, a Cu seed metal is formed to the thickness of about 100 nm. Then, Cu is deposited by electroplating so that the first via holes 21 and the second interconnect grooves 22 are buried with Cu. Thereafter, Cu and the barrier metal film on the second insulating film 7 are removed by CMP to thereby form a second layer interconnect pattern 16 and a plurality of second-to-first vias 15 simultaneously. Here, the above-mentioned steps are similar to the typical dual damascene process and, as far as the similar structure can be obtained, may be replaced by any other appropriate method.

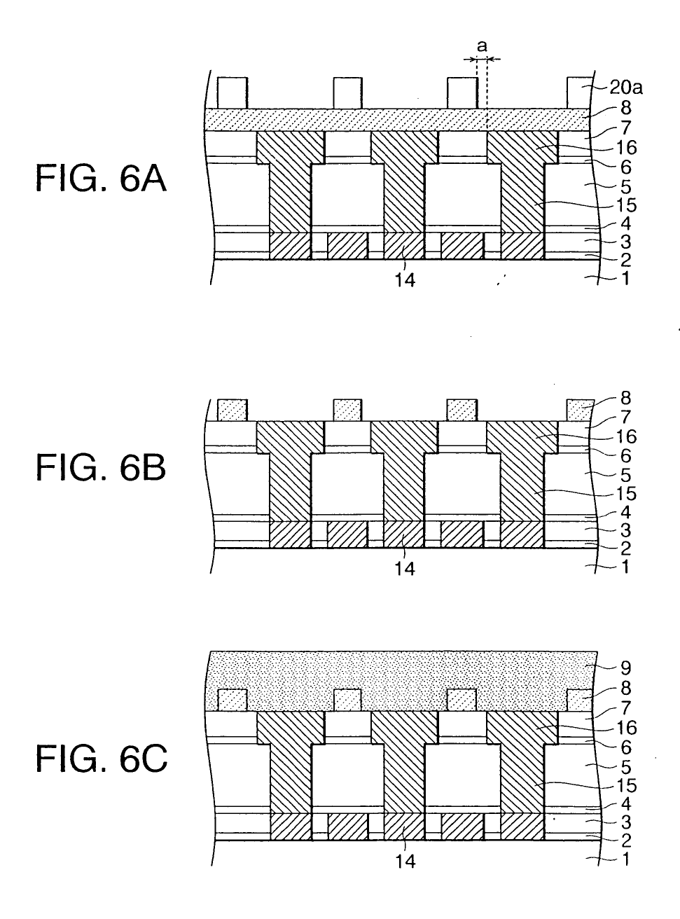

Next, as illustrated in FIG. 6A, on the second insulating film 7, a first cover insulating film 8 made of SiO₂ or the like (a material assuring an etching selectivity with respect to a second cover insulating film 9 which will be formed in a later step) is deposited. The first cover insulating film 8 serves to form a hard mask. The thickness of the first cover insulating film 8 is selected to be the thickness required for the hard mask (namely, the thickness determined taking the shape of the via, the thickness and the material of each layer into consideration).

Thereafter, on the first cover insulating film 8, a resist pattern 20a defining an opening portion of the hard mask is formed. This resist pattern 20a is designed so that the space (depicted by a in FIG. 6A) between the resist pattern 20a and the second layer interconnect pattern 16 is equal to or greater than a total margin of an alignment margin with respect to the second layer interconnect pattern 16 plus a short margin between the second layer interconnect pattern 16 and a third-to-first via 19 which will later be described.

Subsequently, as shown in FIG. 6B, using the resist pattern 20a as a mask, the first cover insulating film 8 is etched by the known dry-etching. Then, the resist pattern 20a is removed, and the first cover insulating film 8 is processed and patterned into a shape substantially coincident with that of the resist pattern 20a.

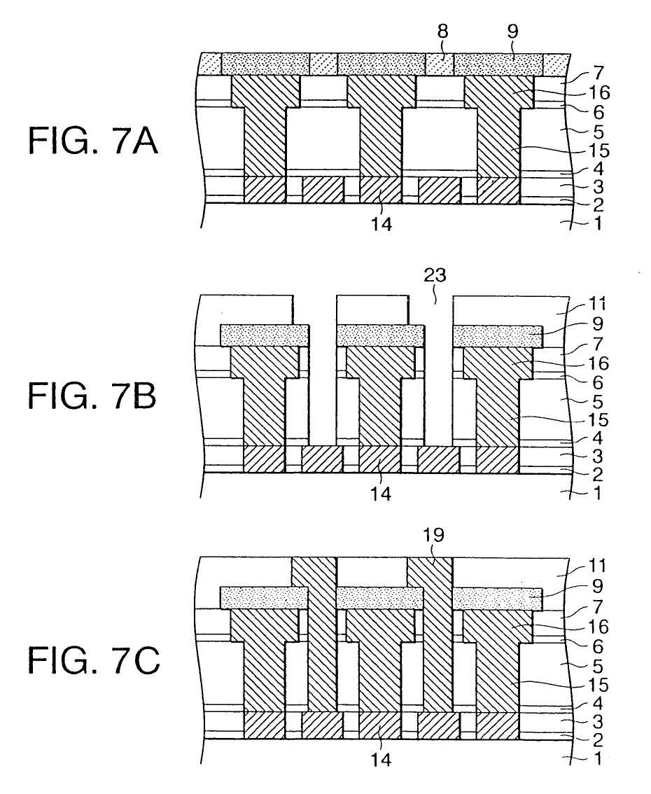

Next, as illustrated in FIG. 6C, the second cover insulating film 9 made of a material (SiNx, SiC, SiCN, or the like) having a sufficiently high etching selectivity with respect to the first cover insulating film 8 is formed so as to cover the first cover insulating film 8 patterned as described above. Thereafter, the second cover insulating film 9 is polished by etch-back or CMP. Consequently, a substantially flat hard mask, in which the first insulating film 8 is buried in the opening portion of the second cover insulating film 9, is formed as illustrated in FIG. 7A.

Subsequently, on the hard mask having the above-described structure, a second interlayer insulating film 11 is deposited. In the aforementioned second conventional example, the hard mask comprising the nitride film mask 24 and the sidewall nitride film 25 has the large irregularity and the region surrounded by the sidewall nitride film 25 has the high aspect ratio. As a consequence, it is difficult to sufficiently and completely bury the second interlayer insulating film 11 in that region and, therefore, the void formation is often caused by the buried defect. On the other hand, in case of the structure according to this embodiment, the first cover insulating film 8 is buried in the opening portion of the second cover insulating film 9 and the hard mask itself has no irregularity. Consequently, the buried defect of the second interlayer insulating film 11 is not caused. Thereafter, on the second interlayer insulating film 11, a resist pattern (not shown) provided with an opening portion having a width equal to or wider than that of the first cover insulating film 8 is formed. Then, using the resist pattern as a mask, etching is carried out by the known dry-etching. As a consequence, each of the second insulating film 7 and the first interlayer insulating film 5 is etched only in an area defined by the opening portion of the second cover insulating film 9 to thereby form a second via hole 23 illustrated in FIG. 7B.

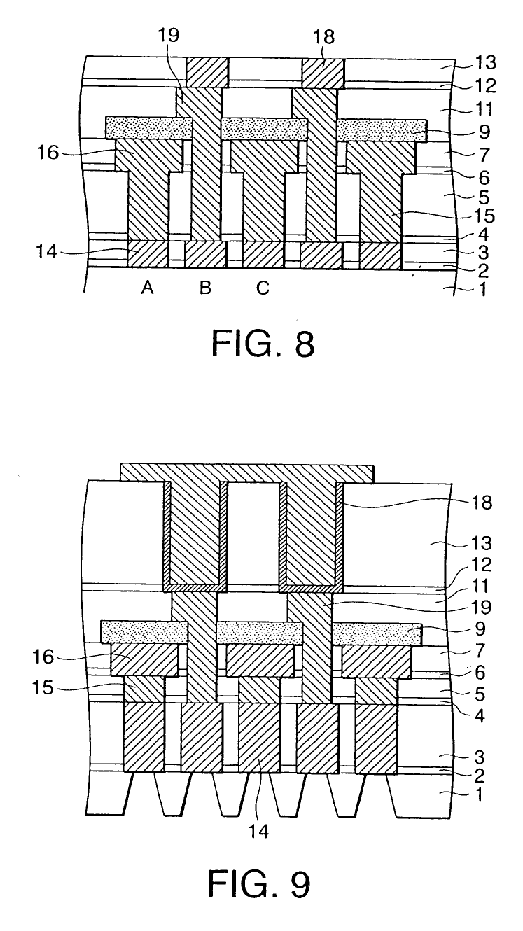

Thereafter, as shown in FIG. 7C, a barrier metal and a Cu seed metal are formed. The barrier metal comprises a single-layer film such as Ti, TiN, Ta, TaN, WN, or the like or a lamination film including two or more layers as a combination of those films. Then, Cu is deposited by electroplating to bury Cu in the second via hole 23. Subsequently, the Cu and the barrier metal on the second interlayer insulating film 11 are removed by CMP to thereby form the third-to-first via 19. In the similar manner, a third layer interconnect pattern 18 is formed on the third-to-first via 19. By repeating the aforementioned steps, the semiconductor device having a desired multilayer structure is completed as illustrated in FIG. 8.

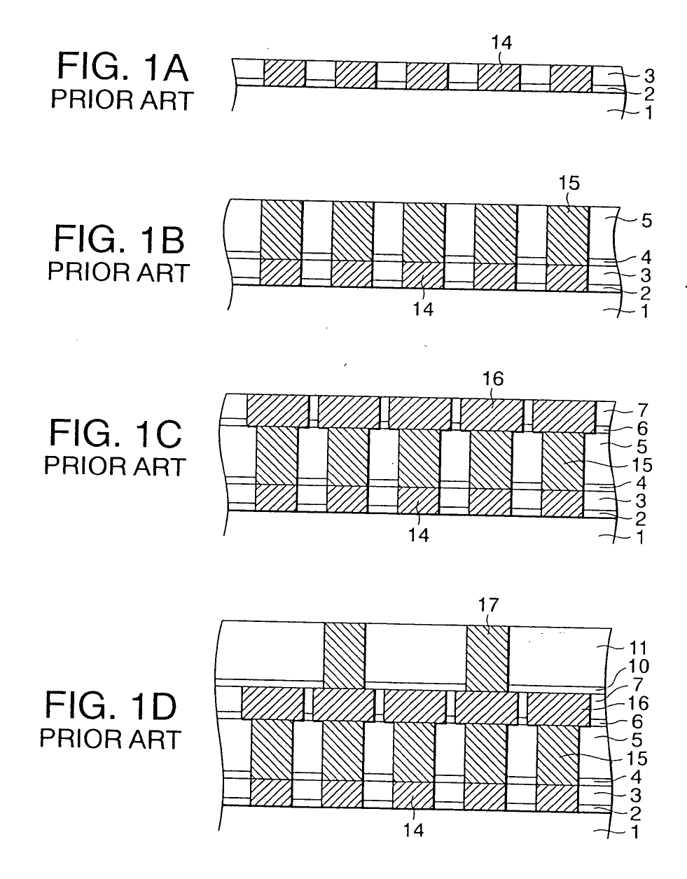

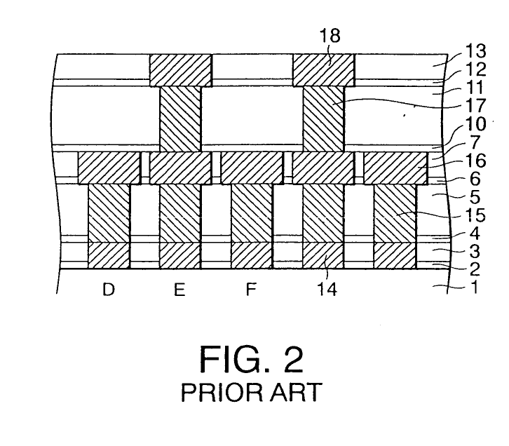

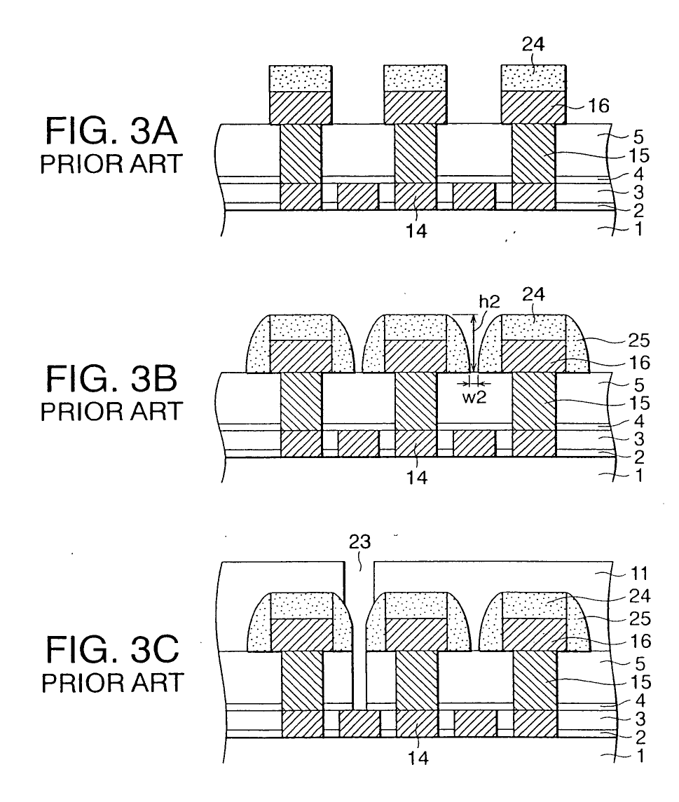

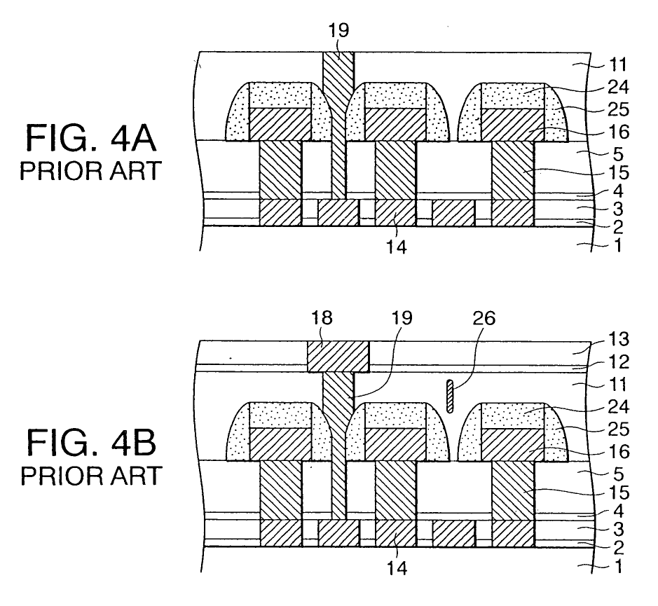

In the foregoing, description has been made of the case where the method of forming the third-to-first via 19 by using the hard mask according to this invention is applied to the dual damascene process in which the second layer interconnect pattern 16 and the second-to-first via 15 are simultaneously formed. However, the method using the hard mask according to this invention is similarly applicable to the single damascene process in which the second layer interconnect pattern 16 and the second-to-first via 15 are independently and individually formed. In this event, after the first layer interconnect pattern 14, the second-to-first via 15 and the second layer interconnect pattern 16 are formed in accordance with the steps illustrated in FIGS. 1A through 1C, the third-to-first via 19 is formed in accordance with the steps illustrated in FIGS. 6A to 7C.

The method of this invention is applicable to any semiconductor device having a damascene structure. Referring to FIG. 9, description will be made of the case where the method of this invention is applied to a semiconductor memory device having a COB structure in which a capacitor element is disposed above a bit line. Specifically, the first layer interconnect pattern 14 serve as cell contacts. Some of the cell contacts are connected to the bit lines (the second layer interconnect pattern 16) through bit contacts (the second-to-first vias 15) while the others are connected to capacitor lower electrodes (the third layer interconnect pattern 18) through capacitor contacts (the third-to-first vias 19). In this structure, an upper electrode (plate electrode) is formed in the capacitor lower electrode of a cylindrical shape through a capacitor insulating film to form a capacitance.

Thus, in the semiconductor device and the method of manufacturing the same according to this embodiment, after the interconnect pattern (in this case, the second layer interconnect pattern 16) is formed, the substantially flat hard mask without the irregularity is formed on the interconnect pattern by the use of the first cover insulating film 8 and the second cover insulating film 9. In this manner, the interlayer insulating film (in this case, the second interlayer insulating film 11) can be readily formed on the hard mask to thereby prevent the void formation caused by the buried defect. In addition, the insulating films (in this case, the second insulating film 7, the third etching stopper film 6, the first interlayer insulating film 5, and the second etching stopper film 4) disposed below the hard mask can be etched in the self-aligned manner. As a consequence, the interconnect pitch (for example, the space between the second interconnect pattern 16 in the paths depicted by A and C in FIG. 8) can be reduced. Moreover, it is possible to prevent the disadvantage that the broadened base of the sidewall film is etched and, as a result, the via diameter is fluctuated.

### Second Embodiment

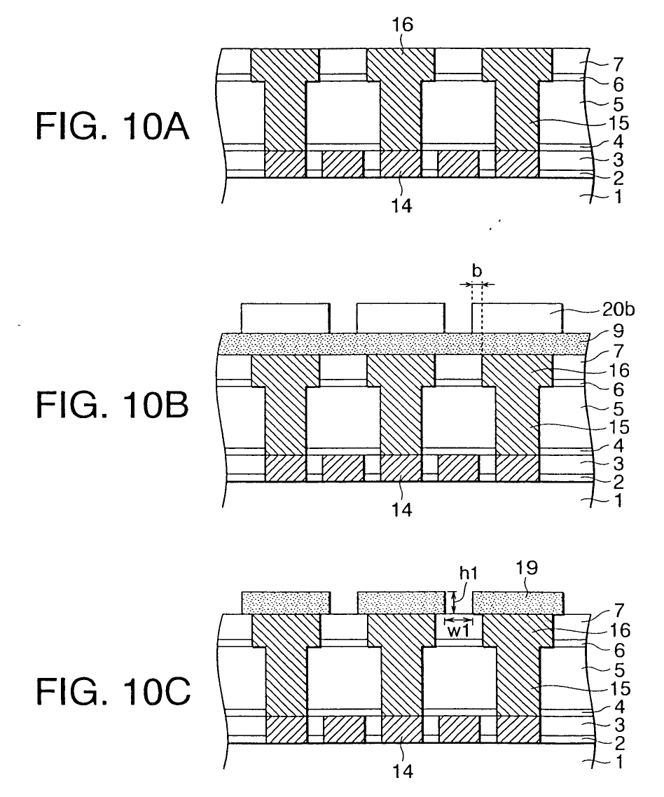

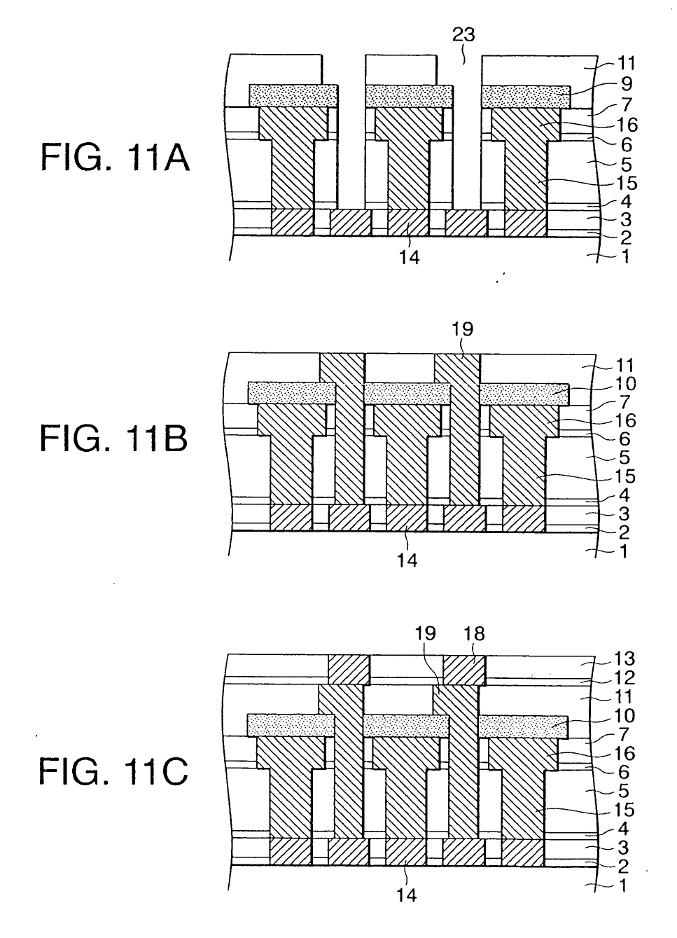

Referring to FIGS. 10A through 11C, description will be made of a semiconductor device and a method of manufacturing the same according to a second embodiment of this invention. In the following, another method of producing the hard mask will be described while the structure of the remaining portions and the method of producing the remaining portions in the second embodiment are similar to those of the first embodiment.

At first, in the manner similar to the first embodiment, on the semiconductor substrate 1 provided with the MOS transistor or the like, the first etching stopper film 2 made of SiNx, SiC, SiCN, or the like and the first insulating film 3 made of SiO₂ or the like are successively deposited by CVD, plasma CVD, or the like. Using the resist pattern formed thereon as the mask, the first interconnect grooves are formed by dry-etching. After the resist pattern is removed, the barrier metal film such as Ti, TiN, Ta, TaN, WN, or the like and Cu are deposited. Then, the wires of the first layer interconnect pattern 14 are buried in the first interconnect grooves by CMP.

Next, on the first insulating film 3, the second etching stopper film 4 made of SiNx, SiC, SiCN, or the like, the first interlayer insulating film 5 made of SiO₂, the low dielectric film, or the like, the third etching stopper film 6 made of SiNx, SiC, SiCN, or the like, and the second insulating film 7 made of SiO₂ or the like are successively formed by CVD, plasma CVD, or the like. Then, using the resist pattern formed thereon as the mask, the first via hole 21 is formed by dry-etching, and, thereafter, the resist pattern is removed.

Subsequently, using the resist pattern formed on the second insulating film 7 as the mask, the second insulating film 7 is etched by dry-etching to thereby form the second interconnect grooves. Thereafter, the exposed part of the third etching stopper film 6 and the second etching stopper film 4 at the bottom of the first via hole 21 are etched. Then, after the resist pattern is removed, the barrier metal film such as Ti, TiN, Ta, TaN, WN, or the like and Cu are deposited. By CMP, the second layer interconnect pattern 16 and the second-to-first via 15 are simultaneously formed so as to obtain the structure illustrated in FIG. 10A.

In the aforementioned first embodiment, the first cover insulating film 8 is deposited on the second insulating film 7. On the other hand, in the second embodiment, the second cover film 9 made of SiNx, SiC, SiCN, or the like is deposited as shown in FIG. 10B in order to simplify the steps. Thereafter, on the second cover insulating film 9, a resist pattern 20b for forming the opening portion of the hard mask is formed. In this event, the resist pattern 20b is designed so that the space (depicted by b in FIG. 10B) between the opening portion of the resist pattern 20b and the second layer interconnect pattern 16 is equal to or greater than the total margin of the alignment margin with respect to the second layer interconnect pattern 16 plus the short margin between the second layer interconnect pattern 16 and the third-to-first via 19.

Subsequently, as illustrated in FIG. 10C, using the resist pattern 20b as the mask, the second cover insulating film 9 is etched by the known dry-etching to thereby form the opening portion. Thus, the hard mask comprising only the second cover insulating film 9 is formed.

Successively, on the hard mask, the second interlayer insulating film 11 is deposited. In the first embodiment, the opening portion of the second cover insulating film 9 is buried with the first cover insulating film 8 and, therefore, the surface of the hard mask is flat without the irregularity. On the other hand, in the second embodiment, the opening portion of the second cover insulating film 9 is left recessed without being filled and, therefore, a small step (difference in height) may be produced.

In the aforementioned second conventional example, the aspect ratio of the region surrounded by the sidewall nitride film 25 is equal to the ratio (h2/w2) between the total film thickness (h2) of the nitride film mask 24 and the second interconnect layer 16 and the opening width (w2). By contrast, in the second embodiment, the aspect ratio is equal to the ratio (h1/w1) between the film thickness (h1) of the second insulating film 7 and the opening width (w1). If the same opening width is applied, the aspect ratio in this embodiment is remarkably decreased. Therefore, the buriability of the second interlayer insulating film 11 can be improved as compared with the second conventional example. Thereafter, on the second interlayer insulating film 11, a resist pattern (not shown) having an opening portion equivalent to or larger than the opening portion of the second cover insulating film 9 is formed. Then, using the resist pattern as the mask, the etching is carried out by the use of the known dry-etching. Consequently, each of the second insulating film 7 and the first interlayer insulating film 5 is etched only in an area defined by the opening portion of the second cover insulating film 9. Thus, a second via hole 23 having the shape illustrated in FIG. 11A is formed.

Thereafter, as illustrated in FIG., 11B, the barrier metal such as Ti, TiN, Ta, TaN, WN, or the like and Cu are deposited. The third -to-first via 19 is formed in the second via hole 23 by CMP. On the third-to-first via 19, the third layer interconnect pattern 18 is formed in the similar manner. By repeating the above-mentioned steps, the semiconductor device having a desired multilayer interconnect structure is completed as shown in FIG. 11C.

As described above, in the semiconductor device and the method of the manufacturing the same according to this embodiment, after the interconnect pattern (herein, the second layer interconnect pattern 16) is formed, the hard mask having less irregularity is formed on the interconnect pattern by the use of the second cover insulating film 9. As a consequence, the buriability of the interlayer insulating film (herein, the second interlayer insulating film 11) formed on the hard mask can be remarkably improved as compared with the aforementioned second conventional example and the production step of the hard mask can be simplified as compared with the aforementioned first embodiment. Moreover, the insulating films located below the hard mask (herein, the second insulating film 7, the third etching stopper film 6, the first interlayer insulating film 5, and the second etching stopper film 4) can be etched in the self-aligned manner by the use of the hard mask. Therefore, it is possible to reduce the interconnect pitch and to avoid the disadvantage that the broadened base of the sidewall is etched and the via diameter is fluctuated.

In the above description, the depth (in the direction orthogonal to the drawing sheet) of the opening portion of the hard mask comprising the second cover insulating film 9 is not specified. If the resist pattern 20b is extended in parallel to the second layer interconnect pattern 16, the opening portion can be formed into a slit-like shape. In the structure of this embodiment, the hard mask is provided with a groove corresponding to the depth of the second cover insulating film 9. However, if the opening portion is formed into the slit-like shape in order to increase the area of the opening portion, the buriability of the second interlayer insulating film 11 can be further improved. The length of the slit is appropriately selected in dependence upon the structure of the interconnect pattern (herein, the third layer interconnect pattern 18) formed thereon. For example, in case of the semiconductor memory device having the COB structure illustrated in FIG. 9, the length may be selected in conformity with the size of the capacitor lower electrode.

In each of the above-mentioned embodiments, the description has been made of the case where the interconnect patterns have a three-layered structure and the third-to-first via is formed by the use of the hard mask according to this invention. However, this invention is not restricted to the above-mentioned embodiments but is also applicable to any semiconductor device in which a fine via hole or a fine interconnect groove is formed by using the hard mask without the irregularity or with small irregularity as well as to a method of manufacturing the same.

As described above, the semiconductor device and the method of manufacturing the same according to this invention exhibits the following effects.

First, it is possible to avoid the void formation and the short-circuiting between the adjacent vias caused by the buried defect of the interlayer insulating film.

The reason will be explained hereinafter. Specifically, the hard mask for forming the via is not formed by the sidewall film but is formed by the use of the cover insulating film disposed on the interconnect pattern after forming the interconnect pattern. Therefore, the hard mask has no irregularity or small irregularity in the opening portion. As a consequence, the buriability of the interlayer insulating film formed thereon can be improved. In particular, according to the method of forming the hard mask by burying the first cover insulating film in the opening portion of the second cover insulating film, the hard mask itself has no step, thus preventing the occurrence of the buried defect reliably.

Second, the interconnect pitch can be reduced. The reason will be explained hereinafter. Specifically, if the interlayer insulating film is deposited on the hard mask and the etching is carried out by the use of the resist pattern formed thereon, the insulating films located below the hard mask are etched in alignment with the opening portion of the hard mask. Therefore, the via having high accuracy can be formed. In case of the sidewall structure, the broadened base of the sidewall film may be etched so that the via diameter is fluctuated. On the other hand, according to this invention, the hard mask in which the opening portion is processed and shaped to be substantially vertical to the substrate surface is used. Therefore, it is possible to control the shape of the via and, as a result, to reduce the design margin.

While this invention has thus far been disclosed in conjunction with a few preferred embodiments thereof, it will be readily possible for those skilled in the art to put this invention into practice in various other manners without departing from the scope of this invention.

What is claimed is:

1. A semiconductor device having an insulating film, comprising:
an interconnect groove or a via hole which is formed in the insulating film;
an interconnect pattern or a via hole which is buried in the interconnect groove or the via hole; and
a substantially flat hard mask which is formed on the interconnect pattern and which is provided with an opening portion having a width narrower than a space between adjacent interconnect patterns and which is made of a material that is etched selectively with the insulating film.

2. A semiconductor device claimed in claim 1, wherein:
the hard mask comprises a slit-like opening portion which is formed in an extending direction of the interconnect pattern located below the hard mask.

3. A semiconductor device having an insulating film, comprising:
an interconnect groove or a via hole which is formed in the insulating film;
an interconnect pattern or a via hole which is buried in the interconnect groove or the via hole;
a first layer interconnect pattern;
a second layer interconnect pattern which is formed on the first layer interconnect pattern;
a third layer interconnect pattern which is formed on the second layer interconnect pattern, the third layer interconnect pattern being connected to the first layer interconnect pattern through a third-first layer interconnection via penetrating a space between adjacent second layer interconnect patterns; and
a substantially flat hard mask which is formed on the second interconnect pattern and which is provided with an opening portion specifying a shape of the third-first layer interconnection via and which is made of a material that is etched selectively with the insulating film.

4. A semiconductor device claimed in claim 3, wherein:
the hard mask comprises a slit-like opening portion which is formed in an extending direction of the interconnect pattern located below the hard mask.

5. A method of manufacturing a semiconductor device, comprising the steps of:
forming an interconnect groove or a via hole in a insulating film formed on a substrate;
forming an interconnect pattern or a via by burying an interconnect material containing at least one of copper and tungsten in the interconnect groove or the via hole; and
forming a substantially flat hard mask which is made of a material that is etched selectively with the insulating film except for a region having a width narrower than a space between adjacent interconnect patterns on the interconnect pattern after forming the interconnect pattern.

6. A method as claimed in claim 5, wherein:
the opening portion of the hard mask is formed to a slit form in an extending direction of the interconnect pattern located below the hard mask.

7. A method of manufacturing a semiconductor device, comprising the steps of:
forming an interconnect groove or a via hole in a insulating film formed on a substrate;
forming an interconnect pattern or a via by burying an interconnect material containing at least one of copper and tungsten in the interconnect groove or the via hole;
forming a first cover insulating film on the interconnect pattern after forming the interconnect pattern;
forming a first resist pattern including an opening portion having a width narrower than a space between adjacent interconnect patterns on the first cover insulating film;
etching the first cover insulating film by using the first resist pattern as a first mask;
depositing a second cover insulating film which is etched selectively with the first cover insulating film so as to cover the first cover insulating film after removing the first resist pattern;
forming a substantially flat hard mask which is buried with the first cover insulating film between the second cover insulating film by polishing the second cover insulating film by etchback or CMP;
forming an interlayer insulating film on the hard mask;
forming a second resist pattern having an opening portion which is equivalent to or wider than that of the first cover insulating film on the interlayer insulating film; and
forming the via hole by etching the interlayer insulating film and the first cover insulating film using the second resist pattern as a second mask and by etching the insulating film using the second cover insulating film as a third mask.

8. A method as claimed in claim 7, wherein:
the second cover insulating film is formed by a material that is etched selectively with the insulating film and the interlayer insulating film.

9. A method as claimed in claim 7, wherein:
the opening portion of the hard mask is formed to a slit form in an extending direction of the interconnect pattern located below the hard mask.

10. A method of manufacturing a semiconductor device, comprising the steps of:
forming an interconnect groove or a via hole in a insulating film formed on a substrate;
forming an interconnect pattern or a via by burying an interconnect material containing at least one of copper and tungsten in the interconnect groove or the via hole;
forming a cover insulating film on the interconnect pattern after forming the interconnect pattern;
forming a first resist pattern including an opening portion having a width narrower than a space between adjacent interconnect patterns on the cover insulating film;
forming a substantially flat hard mask by etching the cover insulating film using the first resist pattern as a first mask;
forming an interlayer insulating film on the hard mask after removing the first resist pattern;
forming a second resist pattern having an opening portion which is equivalent to or wider than that of the first cover insulating film on the interlayer insulating film; and
forming the via hole by etching the interlayer insulating film using the second resist pattern as a second mask and by etching the insulating film using the second cover insulating film as a third mask.

11. Amethod as claimed in claim 10, wherein:
the cover insulating film is formed by a material that is etched selectively with the insulating film and the interlayer insulating film.

12. A method as claimed in claim 10, wherein:
the opening portion of the hard mask is formed to a slit form in an extending direction of the interconnect pattern located below the hard mask.
